(19) United States
(12) Patent Application Publication
(10) Pub. No.: US 2018/0317339 A1
(43) Pub. Date: Nov. 1, 2018

(54) PASSIVE HEAT TRANSPORT SUBSYSTEMS IN HANDHELD ELECTRONIC DEVICES

(71) Applicant: Essential Products, Inc., Palo Alto, CA (US)

(72) Inventors: David John Evans, V, Palo Alto, CA (US); William Francis Leggett, San Jose, CA (US); Joseph Anthony Tate, San Jose, CA (US)

(21) Appl. No.: 15/727,507

(22) Filed: Oct. 6, 2017

Related U.S. Application Data
(60) Provisional application No. 62/492,877, filed on May 1, 2017.

(51) Int. Cl. H05K 7/20

(52) U.S. Cl. CPC H05K 7/20127; H01L 23/467

(57) ABSTRACT

A handheld electronic device including a plurality of electronic components and a channel forming a cavity extending continuously across the handheld electronic device to enable an airflow through the handheld electronic device to an external environment. The handheld electronic device includes an inlet of the channel cavity configured to accept air from the external environment and an outlet of the channel cavity configured to expel heated air to the external environment when the handheld electronic device is oriented such that the airflow moves by natural convection from the inlet toward the outlet.

### CROSS-REFERENCE TO RELATED APPLICATION

This application claims priority to U.S. provisional patent application No. 62/492,877 filed May 1, 2017, which is incorporated herein in its entirety by this reference.

### TECHNICAL FIELD

The disclosed teachings relate to passive heat transport subsystems and, more particularly, to passive heat transport subsystems integrated in handheld electronic devices.

### BACKGROUND

A handheld electronic device is a small computing device such as a smartphone or wearable device. A handheld electronic device can include a combination of complex external and internal components (e.g., electronic, mechanical, optical) that enable a variety of functions. For example, a smartphone can combine features of a personal computer operating system with features of a mobile phone, media player, gaming device, global positioning system (GPS) navigation device, a digital camera, and light source. As handheld electronic devices add more features, the number of components incorporated they include is limited due to the sizes of the handheld electronic devices. Hence, handheld electronic devices are densely packed with components Separate accessories can expand the capabilities of the handheld electronic devices. For example, a digital camera accessory can attach to a handheld electronic device such as a smartphone when needed, and detach when not needed. Although separate additional accessories can expand the capabilities of the handheld devices, they are also densely packed with internal components. Hence, both the handheld electronic devices and their accessories include a combination of complex and diverse components.

The components of the handheld electronic devices and their accessories can generate heat when operating. For example, microprocessors and circuit assemblies include electronic components such as resistors that generate heat when operating. Moreover, certain components such as batteries and illumination devices can individually generate a significant amount of heat. Hence, handheld electronic devices and their accessories are densely packed with components that can generate a significant amount of heat. The increased temperature can damage the handheld electronic devices and their accessories, and even injure users. For example, handheld devices can malfunction if their temperatures increase too high, and even catch fire and burn a user.

### SUMMARY

The disclosed embodiments include a handheld electronic device including electronic components and a channel forming a cavity extending continuously across the handheld electronic device to enable an airflow through the handheld electronic device to an external environment. The handheld electronic device includes an inlet of the channel cavity configured to accept air from the external environment and an outlet of the channel cavity configured to expel heated air to the external environment when the handheld electronic device is oriented such that the airflow moves by natural convection from the inlet toward the outlet. In some embodiments, the handheld electronic device is a smartphone or a camera accessory that can attach to the smartphone.

In some embodiments, the airflow moves by natural convection towards the outlet when the channel is oriented vertically relative to earth, and does not move from natural convection towards the outlet when the channel is oriented horizontally. In some embodiments, the channel is configured to accept heat generated by the electronic components located proximate to the channel.

In some embodiments, the handheld electronic device includes micro-channels configured to accept air from the external environment and expel air to the channel. The air expelled by the micro-channels has a greater temperature compared to the external environment because the micro-channels are configured to accept heat from the electronic components.

In some embodiments, the handheld electronic device includes any combination of a forced convection unit operable to increase a rate of airflow in the channel, a thermosiphon or heat pipe configured to accept heat from the plurality of electronic components and transport the heat toward the outlet, and a heat sink (e.g., including fin structures) permeable to air and thermally coupled to the channel such that the heat sink dissipates heat from the airflow to the external environment, where the heat sink is disposed on the outlet of the channel. In some embodiments, the force convection unit automatically operates under certain conditions but not other conditions.

Other aspects of the technique will be apparent from the accompanying Figures and Detailed Description.

This Summary is provided to introduce a selection of concepts in a simplified form that is further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

FIG. 1A illustrates a bottom perspective view of a camera accessory including a heat transport subsystem according to some embodiments of the present disclosure;

FIG. 1B illustrates a profile view of the camera accessory of FIG. 1A including the heat transport subsystem according to some embodiments of the present disclosure;

FIG. 1C illustrates a top perspective view of the camera accessory of FIG. 1A including the heat transport subsystem according to some embodiments of the present disclosure;

FIG. 2A illustrates a profile view of the camera accessory of FIG. 1A including the heat transport subsystem according to some embodiments of the present disclosure;

FIG. 2B illustrates a cross-sectional view of the camera accessory of FIG. 1A including the heat transport subsystem according to some embodiments of the present disclosure;

FIG. 3A illustrates a perspective view of the camera accessory of FIG. 1A attached to a smartphone including a heat transport subsystem according to some embodiments of the present disclosure;

FIG. 3B illustrates a cross-sectional view of the camera accessory of FIG. 1A attached to the smartphone of FIG. 3A including the heat transport subsystem according to some embodiments of the present disclosure;

FIG. 4A illustrates a profile view of another embodiment of a camera accessory including a heat transport subsystem according to some embodiments of the present disclosure;

FIG. 4B illustrates a cross-sectional view of the camera accessory of FIG. 4A including the heat transport subsystem according to some embodiments of the present disclosure;

FIG. 5A illustrates a profile view of yet another embodiment of a camera accessory including multiple heat transport subsystems according to some embodiments of the present disclosure;

FIG. 5B illustrates a cross-sectional view of the camera accessory of FIG. 5A including the multiple transport subsystems according to some embodiments of the present disclosure; and

FIG. 6 is a block diagram illustrating components of an electronic device in which embodiments of the present disclosure can be implemented.

### DETAILED DESCRIPTION

The embodiments set forth below represent the necessary information to enable those skilled in the art to practice the embodiments and illustrate the best mode of practicing the embodiments. Upon reading the following description in light of the accompanying Figures, those skilled in the art will understand the concepts of the disclosure and will recognize applications of these concepts that are not particularly addressed here. It should be understood that these concepts and applications fall within the scope of the disclosure and the accompanying claims.

The purpose of the terminology used herein is only for describing embodiments and is not intended to limit the scope of the disclosure. Where context permits, words using the singular or plural form may also include the plural or singular form, respectively.

As used herein, unless specifically stated otherwise, terms such as “processing,” “computing,” “calculating,” “determining,” “displaying,” “generating,” or the like, refer to actions or processes of an electronic device that manipulates and transforms data, represented as physical (electronic) quantities within the computer's memory or registers, into other data similarly represented as physical quantities within the device's memory, registers, or other such storage medium, transmission, or display devices.

As used herein, the terms “connected,” “coupled,” or variants thereof, refer to any connection or coupling, either direct or indirect, between two or more elements. The coupling or connection between the elements can be physical, logical, thermal, or a combination thereof.

The disclosed embodiments include electronic devices that include heat transport subsystems. Handheld electronic devices less commonly use heat transport subsystems due to size constraints. Examples of handheld electronic devices include smartphones and their accessories (e.g., camera accessories). Examples of heat transport subsystems include passive heat transport subsystems and, optionally, active heat transport subsystems. A passive heat transport subsystem can passively accept heat from electronic components of a handheld electronic device and passively reject the accepted heat to an external environment. The passive subsystem can include various structures and use various materials that take advantage of natural heat convection to transport heat away from electronic components of an handheld electronic device and expel it to an external environment. On the other hand, examples of active heat transport subsystems includes forced air convection units such as fans.

Some manufacturers of handheld electronic devices incorporate passive heat dissipation mechanisms such as heat sinks and/or active heat dissipation mechanisms such as fans to reduce the temperature of the devices. Unfortunately, heat sinks typically occupy too much space to act as a sole means for heat dissipation, and active heat dissipation mechanisms that run continuously every time the temperature of a handheld electronic devices exceeds a threshold quickly consume resources (e.g., batteries) of the devices that they are intended to benefit.

In some embodiments, a passive heat transport subsystem can include a passive chimney that uses convection of heated air to passively transport heat in a vertical (i.e., perpendicular) direction relative to ground (i.e., earth). In particular, a passive chimney includes one or more channels, each forming a cavity that can enhance the natural ventilation of an electronic device. An inlet of the channel cavity can accept air from an external environment, the air can accept heat from electronic components of the handheld electronic device, transport the heated air along the length of the channel, and reject the heated air to an external environment from an outlet of the channel cavity.

To enable the natural convection of heated air, the outlet of the channel should be positioned at a higher elevation relative to the inlet of the channel. Thus, the effectiveness of the heat transport of a passive chimney depends on the location, length, cross-section, orientation, insulation, and thermal properties of materials used to form a channel that transports heat away from electronic components of an electronic device. For example, heat transport of an electronic device including a passive chimney is enhanced when channels of a passive chimney are oriented vertically from earth because heat naturally rises due to convection.

In some embodiments, a passive heat transport subsystem can include a heat accept subsystem that transports heat to a thermoelectric heat pump. The thermoelectric heat pump consumes electrical energy to actively transport the heat from the heat accept subsystem to another passive subsystem (a heat reject subsystem) that rejects the heat to the external environment. An example of a passive heat accept/reject subsystem includes one or more thermosiphons or heat pipes that use passive two-phase heat exchange for transporting heat based on natural convection.

Specifically, thermosiphons transport heat via a working fluid by using buoyancy and gravitational forces, without the need of a mechanical pump. As the working fluid is heated, the heated (or gasified) working fluid naturally rises up through the thermosiphon via buoyancy forces due to the decreased density of the heated (or gasified) working fluid. Conversely, when the working fluid is cooled, the cooled (or liquefied) working fluid naturally sinks down through the thermosiphon via gravitational forces due to the increased density of the cooled (or liquefied) working fluid. Another example of a passive heat accept/reject subsystem includes a heat-pipe that contains a wicking medium, whereby capillary forces facilitate movement of a working fluid to transport heat.

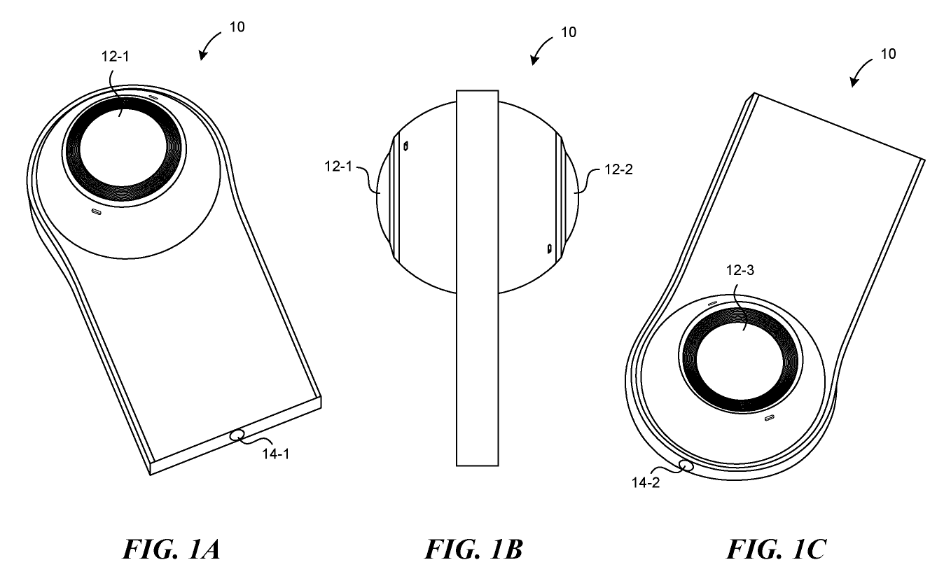

FIGS. 1A through 1C illustrate various views of a camera accessory 10 including a passive heat transport subsystem according to some embodiments of the present disclosure. In particular, FIG. 1A illustrates a bottom perspective view of the camera accessory 10, FIG. 1B illustrates a profile view of the camera accessory 10, and FIG. 1C illustrates a top perspective view of the camera accessory 10.

The camera accessory 10 is an imaging device configured to capture a wide field view of an environment. The camera accessory 10 can include any number of cameras including lenses disposed on any surface of the camera accessory 10. As shown, the camera accessory 10 includes two cameras with respective lenses 12-1 and 12-2. The lens of camera 12-1 faces a first direction, and the lens 12-2 of the second camera faces a second direction, opposite of the first direction.

The camera lenses 12-1 and 12-2 receive light beams from a wide angle view (e.g., a 360-degree view). The curved three-dimensional surface of the camera accessory 10 can take on any shape, such as an ellipsoid, a spheroid, a sphere, a cube with rounded edges, or any three-dimensional (3D) shape. The cameras lenses 12-1 and 12-2 (also referred to collectively as camera lenses 12) can be disposed on the camera accessory 10 in a variety of ways. For example, the camera lenses 12 can be uniformly distributed on the curved 3D surface, placed at the intersection of uniformly distributed longitude and latitude lines, can be more densely distributed in some areas such as a front facing region and/or the back facing region, or the like.

The camera accessory 10 can include several electronic, mechanical, or optical components exposed to an external environment and well known to persons skilled in the art but not shown herein for the sake of brevity. For example, the camera accessory 10 can include an illumination device such as a flash. The camera accessory 10 also includes various internal components and circuitry not shown in FIGS. 1A through 1C. The individual and combination of components of the camera accessory 10 can generate heat, which needs to be transported away from the camera accessory to reduce the risks of damage to the camera accessory 10 or injury to the user of the camera accessory 10.

To mitigate the risks caused by excessive heat generation, the camera accessory 10 includes a passive heat transport subsystem to transport heat away from the camera accessory 10. For example, as shown, the camera accessory 10 has an opening 14-1 and 14-2 of a passive chimney that uses natural convection to passively transport heated air away from the camera accessory 10. In particular, the camera accessory 10 includes a channel having the openings 14-1 and 14-2 that allow air from an external environment to circulate from the external environment, through an internal portion of the camera accessory 10, and back to the external environment.

The channel of the camera accessory 10 enhances the natural ventilation of the camera accessory 10 by accepting heat from internal electronic components of the camera accessory 10, transporting the accepted heat along the length of the channel, and rejecting the heated air back to an external environment. The effectiveness of the passive chimney depends on the orientation of the camera accessory 10. For example, the air inside the channel that is heated by the electronic components of the camera accessory 10 naturally rises in a vertical direction relative to the physical ground (e.g., earth's surface). As such, the heated air of the camera accessory 10 is more effectively rejected when the camera accessory 10 is oriented in a vertical direction compared to a horizontal direction because the channel is oriented along the length of the camera accessory 10.

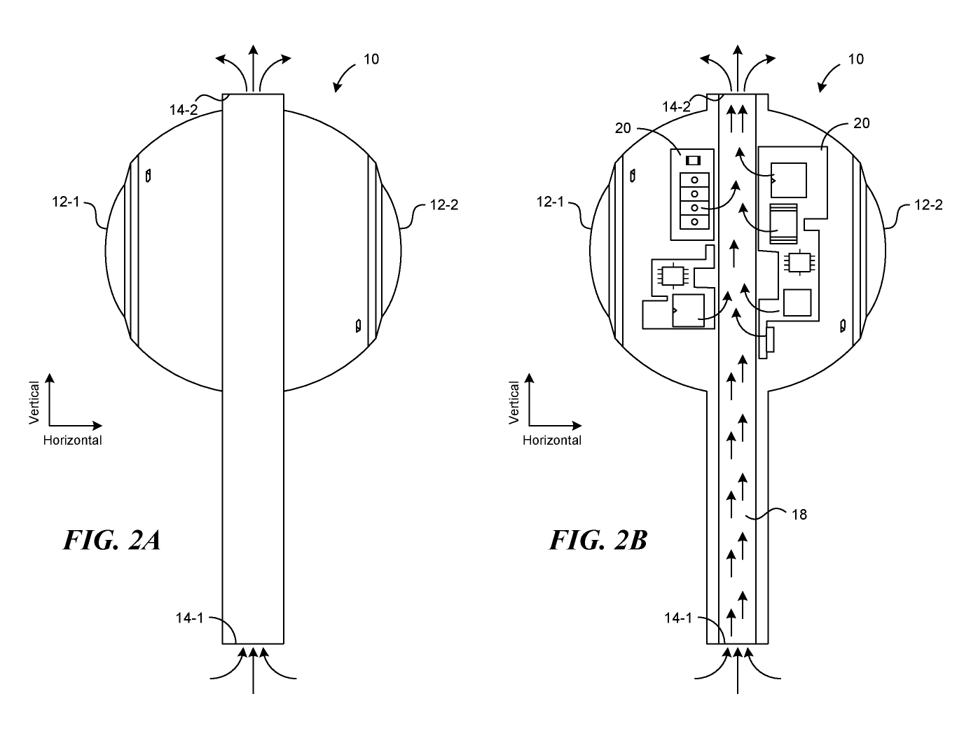

FIG. 2A illustrates a profile view of the camera accessory 10 including a passive heat transport subsystem according to some embodiments of the present disclosure. As shown, the camera accessory 10 is oriented in a vertical direction relative to the ground. The camera lenses 12-1 and 12-2 are facing opposite directions to capture a wide angle view of the environment. The opening 14-1 acts as an inlet to air from the external environment, and the opening 14-2 acts as an outlet for the air back to the external environment.

In particular, the inlet opening 14-1 receives air from the external environment. The received air is transported through a channel (not shown in FIG. 2A) that traverses the length of the camera accessory 10. The internal components (e.g., electronics and circuitry) of the camera accessory 10 heat the air contained in the channel, and the heated air naturally flows to exit the handheld electronic device 10 via the outlet opening 14-2. As such, the air from the external environment passively transports heat away from the camera accessory 10 to reduce its temperature and reduce the risk of damage to the camera accessory 10 and reduce the risk of injury to a user of the camera accessory 10.

FIG. 2B illustrates a cross-sectional view of the camera accessory 10 including the passive heat transport subsystem according to some embodiments of the present disclosure. As shown, a channel 18 of the passive chimney extends continuously from the inlet opening 14-1 to the outlet opening 14-2. The camera accessory 10 includes electronic components 20 that generate heat when operating. Air from the external environment enters the channel 18 through the inlet opening 14-1. The air travels vertically up through the channel 18 and accepts heat from the electronic components 20. The heated air continue to travel vertically up, and out of the outlet opening 14-2. As such, the passive chimney can naturally reduce the temperature of the camera accessory 10.

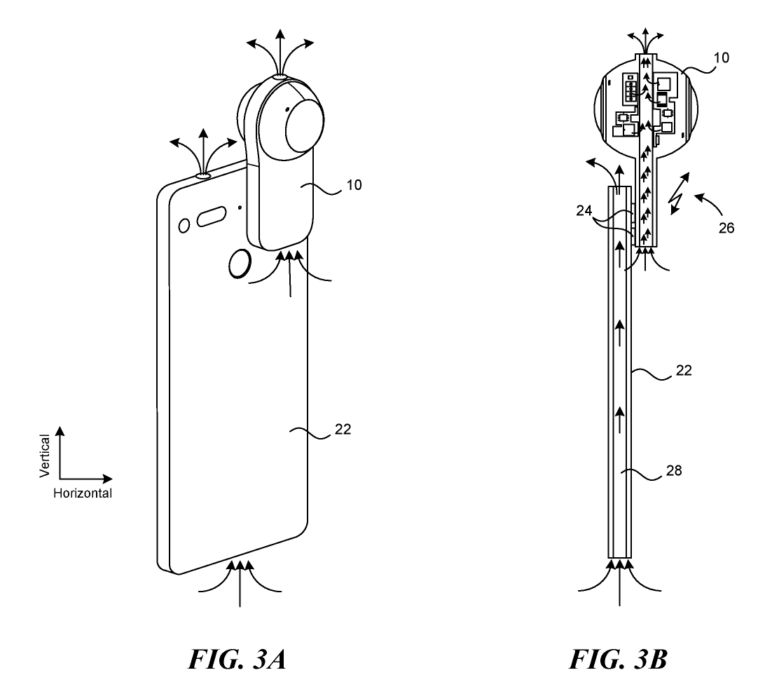

FIG. 3A illustrates a perspective view of the camera accessory 10 attached to a smartphone 22 including a passive subsystem according to some embodiments of the present disclosure. As shown, the smartphone 22 is a handheld mobile electronic device that also includes a passive chimney. The passive chimney of the smartphone 22 is analogous to the passive chimney described with reference to the passive chimney of the camera accessory 10, to reduce the temperature of the smartphone 22 by passively transporting heat to the external environment.

FIG. 3B illustrates a cross-sectional view of the camera accessory 10 attached to the smartphone 22 including a passive subsystem according to some embodiments of the present disclosure. As shown, the camera accessory 10 is attached to the back of the smartphone 22 via an attachment mechanism 24. For example, the attachment mechanism 24 can include magnets that facilitate easily attaching the camera accessory 10 to a metal portion of the smartphone 22. In some embodiments, the camera accessory 10 is controlled by the smartphone 22 via wireless communications 26 such as, for example, via a Bluetooth or Wi-Fi communications link. The channel 28 of the smartphone 22 similarly has inlet and outlet openings to intake air from an environment, accept heat from internal components of the smartphone 22, and then expel the heated air to the external environment.

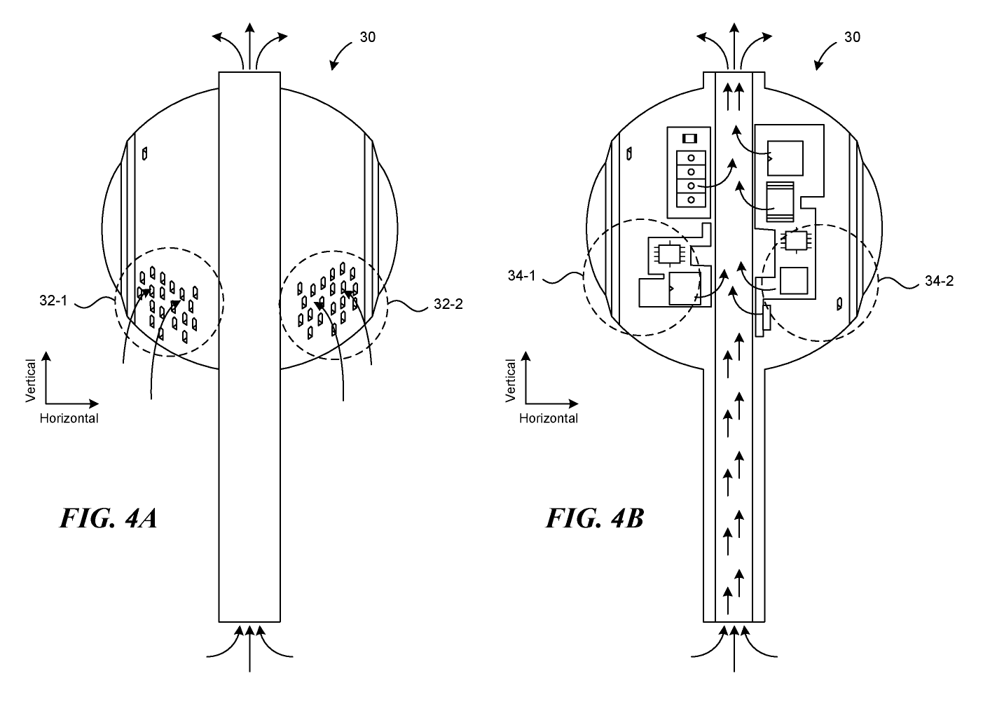

FIG. 4A illustrates a profile view of another embodiment of a camera accessory 30 including a passive subsystem according to some embodiments of the present disclosure. The camera accessory 30 is similar to the camera accessory 10 but additionally includes an array of micro-channels 32-1 and 32-2. The micro-channels include inlets to intake air from the external environment, and transport the air to a main channel that traverses the length of the camera accessory 30.

The air in the micro-channels also accept heat from internal components of the camera accessory 30. As such, the micro-channels can augment the function of a main channel of a passive chimney to accept heat from internal components of the camera accessory 10, and expel the heated air to the external environment. As shown, the micro-channels are oriented in a horizontal direction such that they allow for expelling heat by the camera accessory 30 even when the camera accessory 30 itself is not oriented vertically.

FIG. 4B illustrates a cross-sectional view of the camera accessory 30 including the heat subsystem according to some embodiments of the present disclosure. As shown, internal areas 34-1 and 34-2 of the camera accessory 30 are subjected to the air from the external environment as a result of the micro-channels 32. Hence, the use of the micro-channels 32 increases the internal area of the camera accessory 30 that is subjected to the natural transport of heat from the camera accessory 30 to the external environment.

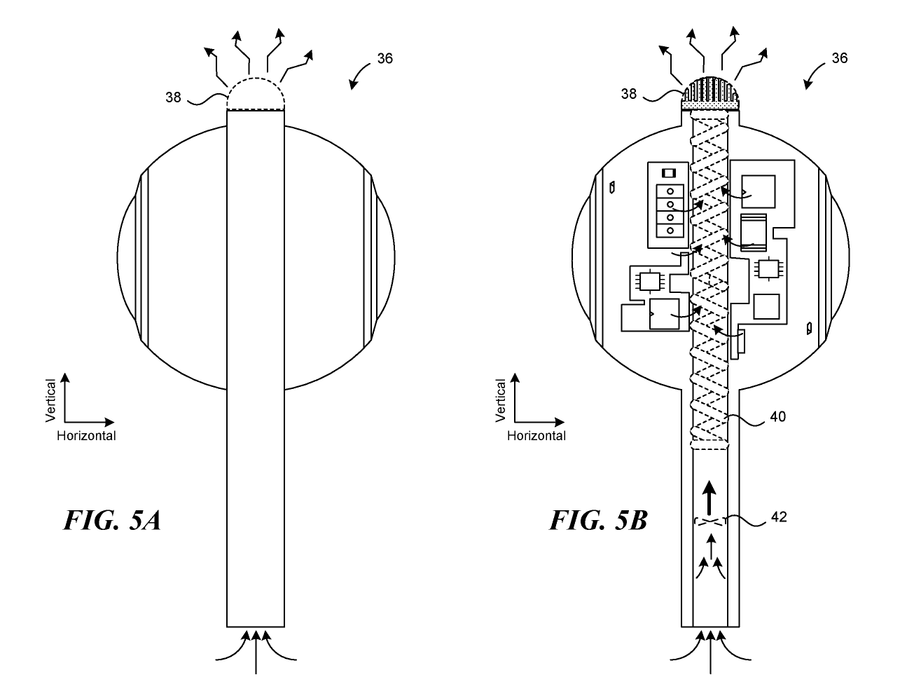

FIG. 5A illustrates a profile view of a camera accessory 36 including passive and active heat transport subsystems according to some embodiments of the present disclosure. The camera accessory 36 is similar to the camera accessory 10 but includes additional optional passive and active subsystems to enhance the effect of the heat accepted and expelled by the camera accessory 36. As shown, the camera accessory 36 has an optional heat sink 38 atop the outlet of a passive chimney. The heat sink 38 can be permeable to airflow from the passive chimney and include fin structures that increase the surface area in contact with heated air from the passive chimney. As such, the heat sink 38 can enhance the dissipation of heat from the camera accessory 36 compared to using a passive chimney alone.

FIG. 5B illustrates a cross-sectional view of the camera accessory 36 including passive and active heat transport subsystems according to some embodiments of the present disclosure. The heat sink 38 accepts heated air from the channel of the passive chimney to enhance dissipation of the air heated by the internal components of the camera accessory 36.

In some embodiments, the camera accessory 36 can include thermosiphons (or heat pipes) to enhance heat transport of the passive chimney. The optional thermosiphons (or heat pipes) are illustrated as tubes that spiral along the inside of the passive chimney. Although shown as a spiral tube, this disclosure is not so limited. For example, the tubes can spiral along the outside of the passive chimney and/or continuously extend vertically along the length of the passive chimney. The thermosiphons accept heat from the internal components of the camera accessory 36 and transport heat via a working fluid using buoyancy and gravitational forces, without the need of a mechanical pump. As the working fluid is heated, the heated (or gasified) working fluid naturally rises up through the thermosiphon via buoyancy forces due to the decreased density of the heated (or gasified) working fluid. Conversely, when the working fluid is cooled, the cooled (or liquefied) working fluid naturally sinks down through the thermosiphon via gravitational forces due to the increased density of the cooled (or liquefied) working fluid. In some embodiments, a heat-pipe that contains a wicking medium can be used, whereby capillary forces facilitate movement of a working fluid to transport heat.

In some embodiments, the heat transport subsystem can include a heat accept subsystem that transports heat to a thermoelectric heat pump (not shown). The thermoelectric heat pump consumes electrical energy to actively transport the heat from the heat accept subsystem to another passive subsystem (a heat reject subsystem) that rejects the heat to the external environment. As such, the passive heat accept/reject subsystems can include thermosiphons or heat pipes in combination with a heat pump to transport heat based on natural convection

In some embodiments, the heat transport system is formed of thermosiphons 40 coupled to the heat sink 38. While not limited thereto, in this example, the heat sink includes one or more fin structures, and can include a forced convection unit such as a fan (not shown) affixed to the heat sink 38. A fan is said to be “affixed” to the heat sink 38 when it is attached, fastened, or otherwise physically joined with the heat sink 38. The fin structures and the forced convection unit can operate to enhance heat extraction from interior components of the camera accessory 36 to an external environment.

In some embodiments, the camera accessory 36 includes an optional forced convection unit 42 located along the passive chimney to enhance the airflow in a desired direction. For example, the forced convection unit 42 can be activated automatically when the camera accessory is oriented horizontally and deactivated automatically when the camera accessory is oriented horizontally. In some embodiments, the camera accessory 36 can maintain a continuous airflow along the passive chimney by activating the forced convection unit 42 to force adequate airflow as needed to maintain the temperature of the camera accessory 36 at a desired temperature when the passive heat transport components alone are insufficient to maintain the desired temperature.

In some embodiments, the camera accessory 36 may include any combination of the heat sink 38, the forced convection unit 42, the thermosiphons (or heat pipes) 40, shown in the figures. While the forced convection unit 42 is affixed in this example, the forced convection unit 42 may alternatively be positioned relative to the other heat transport components so as to direct air toward the heat sink 38 and/or away from the heat sink 38 to the external environment.

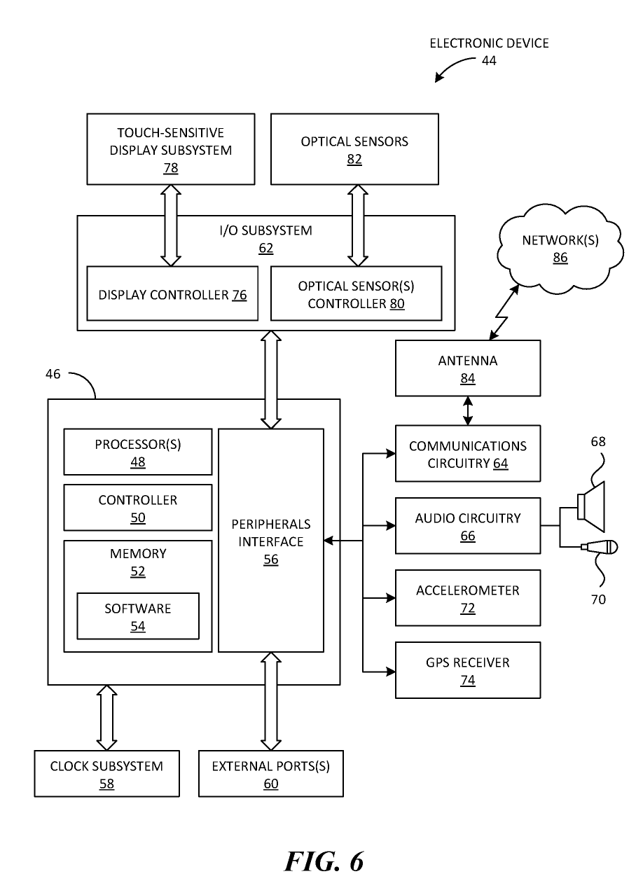

FIG. 6 is a block diagram illustrating components of the electronic device 44 in which embodiments of the present disclosure can be implemented. The electronic device 92 (e.g., handheld electronic device, or accessory device) may include generic components and/or components specifically designed to carry out the disclosed technology. The electronic device 44 may be a standalone device or part of a distributed system that spans networks, locations, machines, or combinations thereof. For example, components of the electronic device 44 may be included in or coupled to a system-on-chip, a single-board computer system, a desktop or laptop computer, a kiosk, a mainframe, a mesh of computer systems, or combinations thereof.

In some embodiments, the electronic device 44 can operate as a server device or a client device in a client-server network environment, or as a peer machine in a peer-to-peer system. In some embodiments, the electronic device 44 may perform one or more steps of the disclosed embodiments in real-time, near real-time, offline, by batch processing, or combinations thereof.

The electronic device 44 can include a processing subsystem 46 that includes one or more processor(s) 48 (e.g., Central Processing Units (CPUs), Application Specific Integrated Circuits (ASICs), and/or Field Programmable Gate Arrays (FPGAs)), a memory controller 50, memory 52 that can store software 54, and a peripherals interface 56. The memory 52 may include volatile memory (e.g., random-access memory (RAM)) and/or non-volatile memory (e.g., read-only memory (ROM)). The memory 52 can be local, remote, or distributed. The electronic device 44 can also include a clock subsystem 58 that controls a timer for use in some embodiments. The components of the electronic device 44 are interconnected over a bus (not shown) operable to transfer data between hardware components.

The peripherals interface 56 is coupled to one or more external port(s) 60, which can connect to an external power source, for example. The peripherals interface 56 is also coupled to an I/O subsystem 62. Other components coupled to the peripherals interface 56 include communications circuitry 64, audio circuitry 66 for a speaker 68 and a microphone 70, an accelerometer 72, a GPS receiver 74 (or Global Navigation Satellite System (GLONASS) or other global navigation system receiver), and other sensors (not shown). The GPS receiver 74 is operable to receive signals concerning the geographic location of the electronic device 44. The accelerometer 72 can be operable to obtain information concerning the orientation (e.g., vertical or horizontal) of electronic device 44 relative to earth.

The I/O subsystem 62 includes a display controller 76 operable to control a touch-sensitive display subsystem 78, which further includes the touch-sensitive display of the electronic device 44. The I/O subsystem 62 also includes an optical sensor(s) controller 80 for one or more optical sensor(s) 82 of the electronic device 44. The I/O subsystem 62 can include other components (not shown) to control physical buttons, such as a “home” button.

The communications circuitry 64 can configure or reconfigure the antenna 84 of the handheld device. In some embodiments, the antenna 84 can be structurally integrated with the electronic device 44 (e.g., embedded in the housing or display screen) or, for example, coupled to the electronic device 44 through the external port(s) 108. The communications circuitry 64 can convert electrical signals to/from electromagnetic signals that are communicated by the antenna 84 to network(s) 86 or other devices. For example, the communications circuitry 64 can include radio frequency (RF) circuitry that processes RF signals communicated by the antenna 84.

In some embodiments, the antenna 84 can be programmatically controlled via the communications circuitry 64. For example, the software 54 may control or contribute to the configuration of the antenna 84 via the communications circuitry 64. For example, the memory 52 may include a database used by the software 54 to configure (or reconfigure) the communications circuitry 64 or antenna 84. The software 54 can be located anywhere in the electronic device 44 or located remotely and communicatively coupled over a network to the electronic device 44. For example, the software 54 can be in a memory 52 to remotely configure the communications circuitry 64 and/or the antenna 84.

The communications circuitry 64 can include circuitry for performing well-known functions such as an RF transceiver, one or more amplifiers, a tuner, oscillator, a digital signal processor, a CODEC chipset, a subscriber identity module (SIM card or eSIM), and so forth. The communications circuitry 64 may communicate wirelessly via the antenna 84 with the network(s) 86 (e.g., the Internet, an intranet and/or a wireless network, such as a cellular network, a wireless local area network (LAN) and/or a metropolitan area network (MAN)) or other devices.

The software 54 can include an operating system (OS) software program, application software programs, and/or modules such as a communications module, a GPS module, and the like. For example, the GPS module can estimate the location of the electronic device 44 based on the GPS signals received by the GPS receiver 74. The GPS module can provide this information to components of the electronic device 44 for use in various applications (e.g., to provide location-based access to service providers).

A software program, when referred to as “implemented in a computer-readable storage medium,” includes computer-readable instructions stored in the memory (e.g., memory 52). A processor (e.g., processor(s) 48) is “configured to execute a software program” when at least one value associated with the software program is stored in a register that is readable by the processor. In some embodiments, routines executed to implement the disclosed embodiments may be implemented as part of OS software (e.g., Microsoft Windows® and Linux®) or a specific software application, component, program, object, module, or sequence of instructions referred to as “computer programs.”

Computer programs typically comprise one or more instructions set at various times in various memory devices of a computing device (e.g., electronic device 44), which, when read and executed by at least one processor (e.g., processor(s) 48), will cause the electronic device 44 to execute functions involving the disclosed embodiments. In some embodiments, a carrier containing the aforementioned computer program product is provided. The carrier is one of an electronic signal, an optical signal, a radio signal, or a non-transitory computer-readable storage medium (e.g., the memory 52).

Operation of a memory device (e.g., memory 52), such as a change in state from a binary one (1) to a binary zero (0) (or vice versa) may comprise a visually perceptible physical change or transformation. The transformation may comprise a physical transformation of an article to a different state or thing. For example, a change in state may involve accumulation and storage of charge or a release of stored charge. Likewise, a change of state may comprise a physical change or transformation in magnetic orientation or a physical change or transformation in molecular structure, such as a change from crystalline to amorphous or vice versa.

Aspects of the disclosed embodiments may be described in terms of algorithms and symbolic representations of operations on data bits stored in memory. These algorithmic descriptions and symbolic representations generally include a sequence of operations leading to a desired result. The operations require physical manipulations of physical quantities. Usually, though not necessarily, these quantities take the form of electric or magnetic signals that are capable of being stored, transferred, combined, compared, and otherwise manipulated. Customarily, and for convenience, these signals are referred to as bits, values, elements, symbols, characters, terms, numbers, or the like. These and similar terms are associated with physical quantities and are merely convenient labels applied to these quantities.

The electronic device 44 may include fewer components than those shown in FIG. 6, or include more components that are not shown nor further discussed herein for the sake of brevity. One having ordinary skill in the art will understand any hardware and software that is included but not shown in FIG. 6. While embodiments have been described in the context of fully functioning handheld electronic devices, those skilled in the art will appreciate that the various embodiments are capable of being distributed as a program product in a variety of forms and that the disclosure applies equally, regardless of the particular type of machine or computer-readable media used to actually effect the embodiments.

While the disclosure has been described in terms of several embodiments, those skilled in the art will recognize that the disclosure is not limited to the embodiments described herein and can be practiced with modifications and alterations within the spirit and scope of the invention. Those skilled in the art will also recognize improvements to the embodiments of the present disclosure. All such improvements are considered within the scope of the concepts disclosed herein. Thus, the description is to be regarded as illustrative instead of limiting.

1. A smartphone comprising:
an outermost housing formed of a front surface, a rear surface opposite of the front surface, and a perimeter of the smartphone connecting the front surface to the rear surface;
a plurality of electronic components contained in the outermost housing;
a channel that is thermally coupled to the plurality of electronic components and forms a cavity extending continuously through the smartphone between two sides of the perimeter, the channel being configured to enable air contained in the cavity to absorb heat dissipated by the plurality of electronic components and enable an airflow from an external environment through the channel of the smartphone and back to the external environment;
an air inlet of the cavity at one of the two sides of the perimeter, the air inlet being configured to accept air from the external environment; and
an air outlet of the cavity at another of the two sides of the perimeter, the air outlet being configured to expel air heated by the plurality of electronic components to the external environment when the channel is oriented vertically relative to earth such that the heated air flows by natural convection from the air inlet toward the air outlet via the channel, wherein temperature of air is cooler at the air inlet compared to temperature of air at the air outlet.

2. (canceled)

3. The smartphone of claim 1, wherein the heated air does not flow due to natural convection across the channel towards the air outlet when the channel is oriented horizontally relative to earth.

4. The smartphone of claim 1, wherein the channel is configured to accept heat generated by the plurality of electronic components located proximate to the channel.

5. (canceled)

6. (canceled)

7. The smartphone of claim 1, further comprising:
a plurality of micro-channels configured to accept air from the external environment and expel air to the channel, wherein air expelled from the micro-channels is hotter than the air accepted by the micro-channels because the micro-channels are configured to contain air that accepts heat from the plurality of electronic components.

8. The smartphone of claim 1, further comprising:
a heatsink disposed at the air outlet and being permeable to airflow, the heatsink being thermally coupled to the channel such that the heatsink dissipates heat from the heated air contained in the cavity of the channel to the external environment, wherein the heatsink includes a plurality of fin structures.

9. The smartphone of claim 1, further comprising:
a thermosiphon configured to accept heat from the plurality of electronic components and transport the heat to the air outlet of the channel in accordance with thermosiphon principals.

10. The smartphone of claim 1, further comprising:
a heat pipe configured to accept heat from the plurality of electronic components and transport the heat to the air outlet of the channel in accordance with heat pipe principals.

11. The smartphone of claim 1, further comprising:
a heatsink disposed at the air outlet and being permeable to airflow, the heatsink being thermally coupled to the channel such that the heatsink dissipates heat from the heated air contained in cavity of the channel to the external environment, wherein the heatsink includes a plurality of fin structures; and
a thermosiphon or heat pipe configured to accept heat from the plurality of electronic components and transport the heat to the air outlet of the channel, where the thermosiphon or heat pipe and the heatsink form a thermally continuous structure.

12. The smartphone of claim 1, further comprising:
a forced convection unit operable to increase a rate of airflow in the channel.

13. The smartphone of claim 1, further comprising:
a forced convection unit configured to activate and increase a rate of airflow in the cavity when each of the channel is oriented parallel to ground or a temperature of the smartphone exceeds a threshold temperature, and is configured to deactivate when the channel is oriented perpendicular to ground or the temperature of the smartphone is below the threshold temperature.

14. The smartphone of claim 1, further comprising:
a forced convection unit operable to increase a rate of airflow in the channel; and
a thermosiphon configured to accept heat from the plurality of electronic components and transport heat toward the air outlet of the channel in accordance with thermosiphon principals; and
a heatsink permeable to air and thermally coupled to the channel such that the heatsink dissipates heat from the airflow to an external environment, the heat sink being disposed on the air outlet of the channel.

15. A camera accessory of a smartphone, the camera accessory comprising:
an outmost housing of the camera accessory;
a plurality of cameras including a plurality of electronic components contained in the outmost housing;
a channel that is thermally coupled to the plurality of electronic components and extends continuously through the camera accessory to form a cavity for airflow through the camera accessory, the channel being configured to enable air contained in the cavity to absorb heat dissipated by the plurality of electronic components and enable an airflow from an external environment through the channel of the camera accessory and back to the external environment;
an air inlet of the channel formed by traversing the outmost housing, the air inlet being configured to enable the cavity to accept air from the external environment; and
an air outlet of the channel formed by traversing the outmost housing, the air outlet being configured to expel air heated by the plurality of electronic components to the external environment when the channel is oriented perpendicular to earth such that the heated air flows in the cavity by natural convection from the air inlet to the air outlet of the channel, wherein temperature of air is cooler at the air inlet compared to temperature of air at the air outlet.

16. The camera accessory of claim 15, further comprising:
a plurality of micro-channels configured to accept air from the external environment and expel air to the channel, wherein air expelled from the micro-channels is hotter than air accepted by the micro-channels because the air contained in the micro-channels are configured to accept heat from the plurality of electronic components.

17. The camera accessory of claim 15, further comprising:
a forced convection unit operable to increase a rate of airflow in the channel;
a thermosiphon configured to accept heat from the plurality of electronic components and transport the heat toward the air outlet of the channel in accordance with thermosiphon principals; and
a heatsink permeable to air and thermally coupled to the channel such that the heatsink dissipates heat from the airflow to an external environment, the heatsink being disposed on the air outlet of the channel.

18. A handheld electronic device comprising:
a hollow channel extending through the handheld electronic device, the hollow channel being configured to enable air contained in the hollow channel to absorb heat dissipated by a plurality of electronic components contained in the handheld electronic device, and enable airflow from an external environment through the hollow channel and back to the external environment;
an air inlet of the hollow channel traversing an outmost surface of the handheld electronic device, the air inlet being configured to accept air from the external environment; and
an air outlet of the hollow channel configured to expel air to the external environment, wherein a temperature of the expelled air is greater than a temperature of the accepted air because heat is transferred from the plurality of electronic components to air contained in the hollow channel as the air flows from the air inlet to the air outlet by natural convection when the hollow channel is oriented perpendicular to earth.

19. The handheld electronic device of claim 18, wherein the handheld electronic device is a digital camera accessory for a smartphone.

20. The handheld electronic device of claim 18, wherein the handheld electronic device is a smartphone.
